(19) United States
(12) Patent Application Publication
(10) Pub. No.: US 2015/0333162 A1
(43) Pub. Date: Nov. 19, 2015

(54) METHODS OF FORMING NANOWIRE DEVICES WITH METAL-INSULATOR-SEMICONDUCTOR SOURCE/DRAIN CONTACTS AND THE RESULTING DEVICES

(71) Applicant: GLOBALFOUNDRIES Inc., Grand Cayman (KY)

(72) Inventors: Guillaume Bouche, Albany, NY (US); Jing Wan, Malta, NY (US); Andy C. Wei, Queensbury, NY (US); Shao-Ming Koh, Clifton Park, NY (US)

(73) Assignee: GLOBALFOUNDRIES Inc., Grand Cayman (KY)

(21) Appl. No.: 14/279,495

(22) Filed: May 16, 2014

(51) Int. Cl. H01L 29/775; H01L 21/768; H01L 29/66

(52) U.S. Cl. CPC H01L 29/775; H01L 29/66439; H01L 21/76879

(57) ABSTRACT

A device includes a gate structure and a nanowire channel structure positioned under the gate structure. The nanowire channel structure includes first and second end surfaces. The device further includes a first insulating liner positioned on the first end surface and a second insulating liner positioned on the second end surface. The device further includes a metal-containing source contact positioned on the first insulating liner and a metal-containing drain contact positioned on the second insulating liner.

### BACKGROUND OF THE DISCLOSURE

1. Field of the Disclosure

The present disclosure generally relates to the formation of semiconductor devices and, more specifically, to various methods of forming nanowire devices with MIS (Metal-Insulator-Semiconductor) source/drain contacts and the resulting devices.

2. Description of the Related Art

The fabrication of advanced integrated circuits, such as CPUs (central processing units), storage devices, ASICs (application specific integrated circuits) and the like, requires the formation of a large number of circuit elements in a given chip area according to a specified circuit layout, wherein so-called metal oxide semiconductor field effect transistors (MOSFETs or FETs) represent one important type of circuit element that substantially determines performance of the integrated circuits. A FET is a planar device that typically includes a source region, a drain region, a channel region that is positioned between the source region and the drain region, and a gate structure positioned above the channel region. These elements are sometimes referred to as the source, drain, channel and gate, respectively. Current flow through the FET is controlled by controlling the voltage applied to the gate electrode. For example, for an NMOS device, if there is no voltage applied to the gate electrode, then there is no current flow through the NMOS device (ignoring undesirable leakage currents, which are relatively small). However, when an appropriate positive voltage is applied to the gate electrode, the channel region of the NMOS device becomes conductive, and electrical current is permitted to flow between the source region and the drain region through the conductive channel region.

To improve the operating speed of FETs, and to increase the density of FETs on an integrated circuit device, device designers have greatly reduced the physical size of FETs over the years. More specifically, the channel length of FETs has been significantly decreased, which has resulted in improving the switching speed of FETs. However, decreasing the channel length of a FET also decreases the distance between the source region and the drain region. In some cases, this decrease in the separation between the source and the drain makes it difficult to efficiently inhibit the electrical potential of the source region and prevent the channel from being adversely affected by the electrical potential of the drain. This is sometimes referred to as a short channel effect, wherein the characteristic of the FET as an active switch is degraded.

In contrast to a FET, which has a planar structure, there are so-called 3D devices, such as an illustrative FinFET device, which is a three-dimensional structure. More specifically, in a FinFET, a generally vertically positioned fin-shaped active area is formed, and a gate electrode encloses both sides and an upper surface of the fin-shaped active area to form a tri-gate structure so as to use a channel having a three-dimensional structure instead of a planar structure. In some cases, an insulating cap layer, e.g. silicon nitride, is positioned at the top of the fin and the FinFET device only has a dual-gate structure. Unlike a planar FET, in a FinFET device, a channel is formed perpendicular to a surface of the semiconducting substrate, which reduces the physical size of the semiconductor device. Also, in a FinFET, improved gate control leads to better short channel effects. When an appropriate voltage is applied to the gate electrode of a FinFET device, the surfaces (and the inner portion near the surface) of the fins, i.e., the substantially vertically oriented sidewalls and the top upper surface of the fin with inversion carriers, contributes to current conduction. In a FinFET device, the “channel-width” is approximately two times (2×) the vertical fin-height plus the width of the top surface of the fin, i.e., the fin width. Multiple fins can be formed in the same footprint as that of a planar transistor device. Accordingly, for a given plot space (or footprint), FinFETs tend to be able to generate significantly higher drive current than planar transistor devices. Additionally, the leakage current of FinFET devices after the device is turned “OFF” is significantly reduced as compared to the leakage current of planar FETs due to the superior gate electrostatic control of the “fin” channel on FinFET devices.

Another form of 3D semiconductor device employs so-called nanowire structures for the channel region of the device. There are several known techniques for forming such nanowire structures. As the name implies, at the completion of the fabrication process, the nanowire structures typically have a generally circular cross-sectional configuration. Nanowire devices are considered to be one option for solving the constant and continuous demand for semiconductor devices with smaller feature sizes. However, the manufacture of nanowire devices is a very complex process.

FIGS. 1A-1F depict one illustrative example of how nanowire devices may be fabricated. FIG. 1A is a simplified view of an illustrative nanowire device 100 at an early stage of manufacturing that is formed on a semiconducting substrate 10. At the point of fabrication depicted in FIG. 1A, various layers of semiconducting material 11, 12, 13 and 14 are formed above the substrate 10. In general, in the depicted example, the layers 11 and 13 include a semiconductor material that may be selectively removed or etched relative to the materials used for the semiconducting material layers 12 and 14. As described more fully below, in the channel region of the device 100, portions of the semiconductor material layers 11 and 13 will be removed while the semiconducting material layers 12 and 14 are left in place as nanowires. Thus, the portions of the semiconducting material layers 11 and 13 within the channel region of the device are sacrificial in nature. The semiconductor materials 11, 12, 13 and 14 may include a variety of different materials such as, for example, silicon, a doped silicon, silicon/germanium, III-V compound, germanium, germanium-based or silicon-based compound etc., and they may be formed to any desired thickness using any appropriate process, e.g., an epitaxial growth process, deposition plus ion implantation, etc. In one embodiment, the semiconducting material layers 11 and 13 may be made from silicon/germanium, while the semiconducting material layers 12 and 14 may be made of silicon.

The gate structure 25 may include a variety of different materials and a variety of configurations. As shown, the gate structure 25 includes a gate insulation layer 25A, a gate electrode 25B and a gate cap layer 25C. A deposition or thermal growth process may be performed to form the gate insulation layer 25A, which may be made of silicon dioxide in one embodiment. Thereafter, the gate electrode 25B and the gate cap layer 25C may be deposited above the device 100, and the layers may be patterned using photolithographic and etching techniques. The gate electrode 25B may include a variety of materials, such as polysilicon or amorphous silicon. Finally, sidewall spacers 28 may be formed adjacent to the gate structure 25. The sidewall spacers 28 may be formed by depositing a layer of spacer material, such as silicon nitride, and thereafter performing an anisotropic etching process to define the spacers 28.

Next, as shown in FIG. 1B, one or more etching processes are performed to remove the exposed portions of the material layers 11-14 that are not covered by the gate structure 25 and the spacers 28. The etching processes may include dry etching and wet etching techniques to remove materials from the device 100.

Next, as shown in FIG. 1C, layers 11 and 13 are selectively recessed using one or more etching processes such that they have a shorter length (in the current transport direction), as viewed in cross-section, than the layers 12 and 14. In at least one embodiment, the layers 11 and 13 are recessed such that the ends of the recessed materials 11 and 13 are approximately aligned with the interface between the sidewall spacers 28 and the gate electrode 25B as viewed in cross-section.

Next, as shown in FIG. 1D, a layer of material 30 is conformably deposited over the substrate 10 and the gate structure 25. In various embodiments, the layer 30 may be made of a low-k material (k value of about 3.3 or less), a nitride, an oxide or a silicon oxycarbide material. The thickness of the layer being deposited may vary depending upon the application. The layer 30 is formed so as to overfill the cavities created by the previous recess etching process performed on the layers 11 and 13.

Next, as shown in FIG. 1E, this layer 30 is etched to leave only the portions 30A adjacent to the recessed, shortened layers 11 and 13.

FIG. 1F depicts the device 100 after raised epitaxial (epi) source/drain regions 97 were formed on the device by performing known epi deposition processes. As depicted, the epi source/drain regions 97 will engage the ends of the material layers 12 and 14, which will become the nanowires for the nanowire device 100. The depicted arrangement may cause several problems. The presence of the raised epi source/drain regions 97 may lead to high access resistance to individual nanowires 12, 14 (the channel region of the device 100), and may result in uneven access resistance to all of the nanowires in a stacked nanowire device. In particular, there may be defects present at the interface between the epi source/drain regions 97 and the nanowires 12, 14 that can result in degradation of the performance of the nanowire device 100.

Device manufacturers are under constant pressure to produce integrated circuit products with increased performance and lower production cost relative to previous device generations. Thus, device designers spend a great amount of time and effort to maximize device performance while seeking ways to reduce manufacturing costs and improve manufacturing reliability. The present disclosure is directed to various methods of forming nanowire devices with MIS (Metal-Insulator-Semiconductor) source/drain contacts and the resulting devices to realize such gains. Additionally, the methods and devices disclosed herein reduce or eliminate one or more of the problems identified above.

### SUMMARY

The following presents a simplified summary of the disclosure in order to provide a basic understanding of some aspects of the disclosure. This summary is not an exhaustive overview. Its sole purpose is to present some concepts in a simplified form as a prelude to the more detailed description that is discussed later.

Generally, the present disclosure is directed to various methods of forming nanowire devices with MIS (Metal-Insulator-Semiconductor) source/drain contacts and the resulting devices. One illustrative device disclosed herein includes a gate structure and a nanowire channel structure positioned under the gate structure. The nanowire channel structure includes first and second end surfaces. A first insulating liner is positioned on the first end surface, and a second insulating liner is positioned on the second end surface. The device further includes a metal-containing source contact positioned on the first insulating liner and a metal-containing drain contact positioned on the second insulating liner.

An illustrative method disclosed herein includes forming a nanowire channel structure positioned under a gate structure, the nanowire channel structure including first and second end surfaces. The method further includes depositing a first insulating liner on the first end surface and depositing a second insulating liner on the second end surface. The method further includes forming a metal-containing source contact on the first insulating liner and forming a metal-containing drain contact on the second insulating liner.

Another illustrative method disclosed herein includes forming a sacrificial contact structure including one or more layers of insulation material. The method further includes forming an insulating material around the sacrificial contact structure and removing the sacrificial contact structure to form a contact opening within the insulating material. The method further includes depositing an insulating liner, within the contact opening, on an end surface of a nanowire channel structure. The method further includes forming a metal-containing contact on the insulating liner within the contact opening.

### BRIEF DESCRIPTION OF THE DRAWINGS

The disclosure may be understood by reference to the following description taken in conjunction with the accompanying drawings, in which like reference numerals identify like elements, and in which:

FIGS. 1A-1F depict cross-sectional views of an illustrative prior art nanowire device; and

FIGS. 2A-2J depict various novel methods disclosed herein of forming nanowire devices with MIS source/drain contacts and the resulting novel nanowire devices.

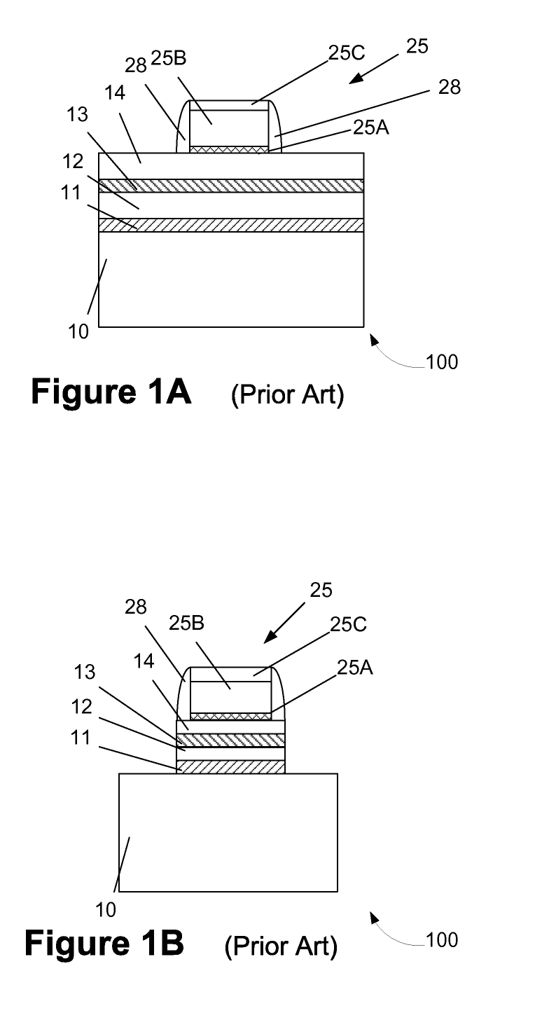

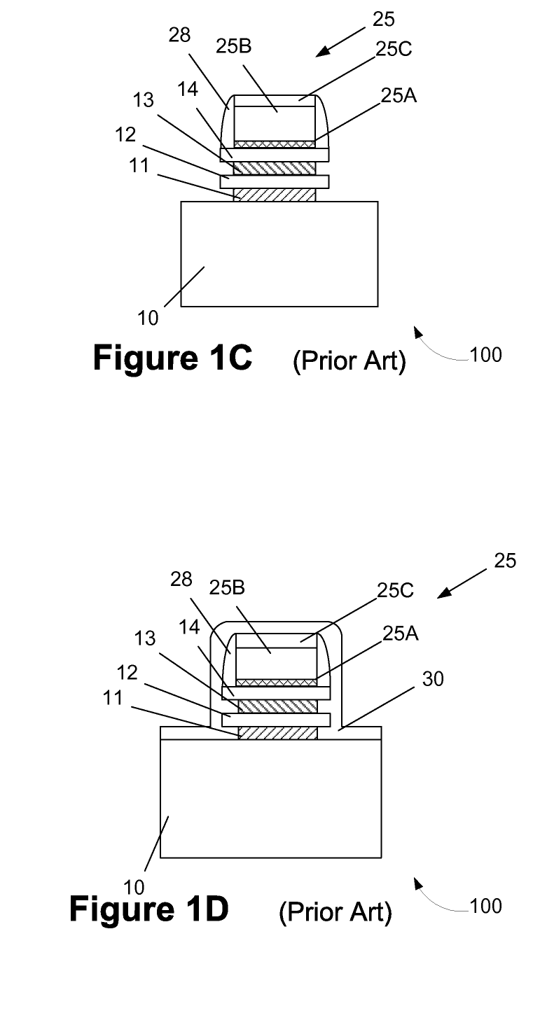

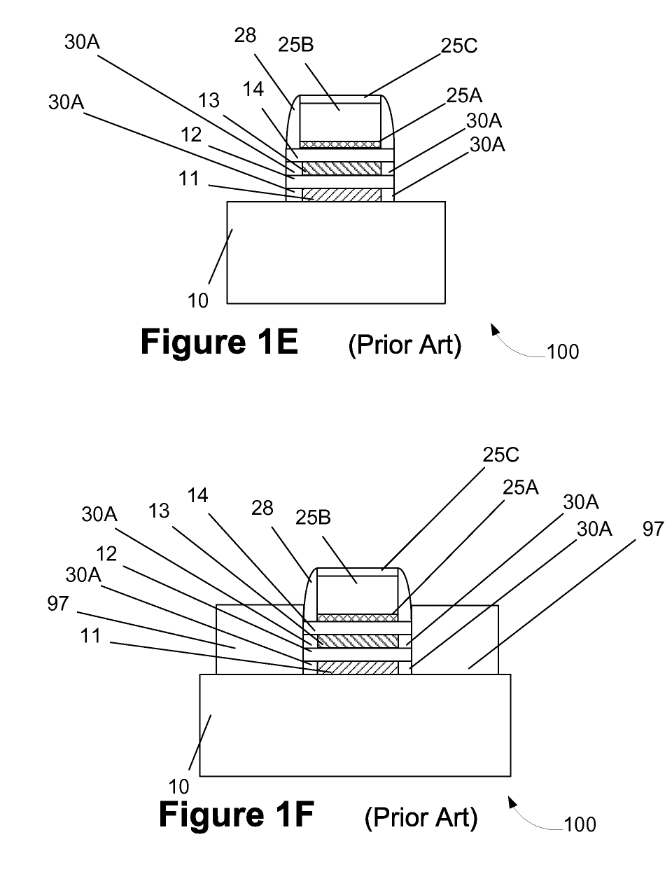

While the subject matter disclosed herein is susceptible to various modifications and alternative forms, specific embodiments thereof have been shown by way of example in the drawings and are herein described in detail. It should be understood, however, that the description herein of specific embodiments is not intended to limit the disclosure to the particular forms disclosed, but on the contrary, the intention is to cover all modifications, equivalents, and alternatives falling within the spirit and scope of the disclosure as defined by the appended claims.

### NOTATION AND NOMENCLATURE

Certain terms are used throughout the disclosure to refer to particular components. However, different entities may refer to a component by different names. This document does not intend to distinguish between components that differ in name but not function. The terms “including” and “comprising” are used herein an open-ended fashion, and thus mean “including, but not limited to.”

### DETAILED DESCRIPTION

The present subject matter will now be described with reference to the attached figures. Various structures, systems, and devices are schematically depicted in the drawings for purposes of explanation only. The attached drawings are included to describe and explain illustrative examples of the present disclosure. The words and phrases used herein should be understood and interpreted to have a meaning consistent with the understanding of those words and phrases by those in the industry. No special definition of a term or phrase, i.e., a definition that is different from the ordinary and customary meaning as understood by those in the industry, is intended to be implied by consistent usage of the term or phrase herein. To the extent that a term or phrase is intended to have a special meaning, such a special definition will be expressly set forth in the specification in a definitional manner that directly and unequivocally provides the special definition for the term or phrase.

The present disclosure is directed to various methods of forming nanowire devices with MIS source/drain contacts and the resulting devices. As will be readily apparent, the present method is applicable to a variety of devices, including, but not limited to, logic devices, memory devices, etc., and the methods disclosed herein may be employed to form N-type or P-type semiconductor devices. With reference to the attached figures, various illustrative embodiments of the methods and devices disclosed herein will now be described in more detail.

In the depicted example, the device 200 will be disclosed in the context of using FinFET formation techniques. However, the present disclosure should not be considered to be limited to the examples depicted herein. The substrate may include a variety of configurations, such as the depicted bulk silicon configuration. The substrate may also include a silicon-on-insulator (SOI) configuration that includes a bulk silicon layer, a buried insulation layer, and an active layer, wherein semiconductor devices are formed in and above the active layer in various embodiments. Thus, the terms “substrate” or “semiconducting substrate” should be understood to cover all substrate configurations. The substrate may also be made of materials other than silicon.

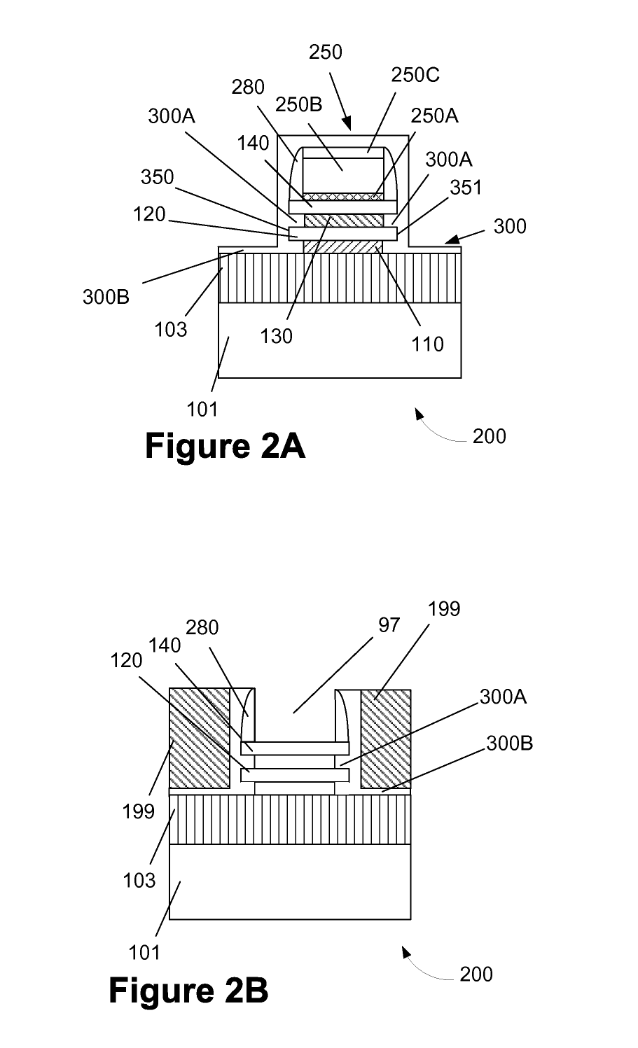

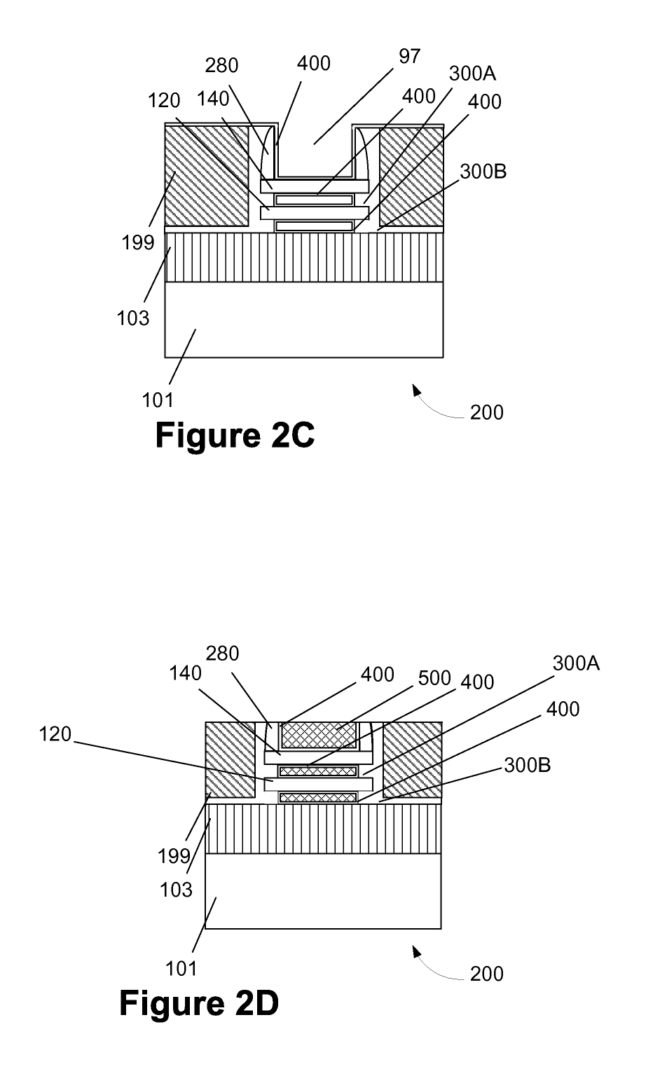

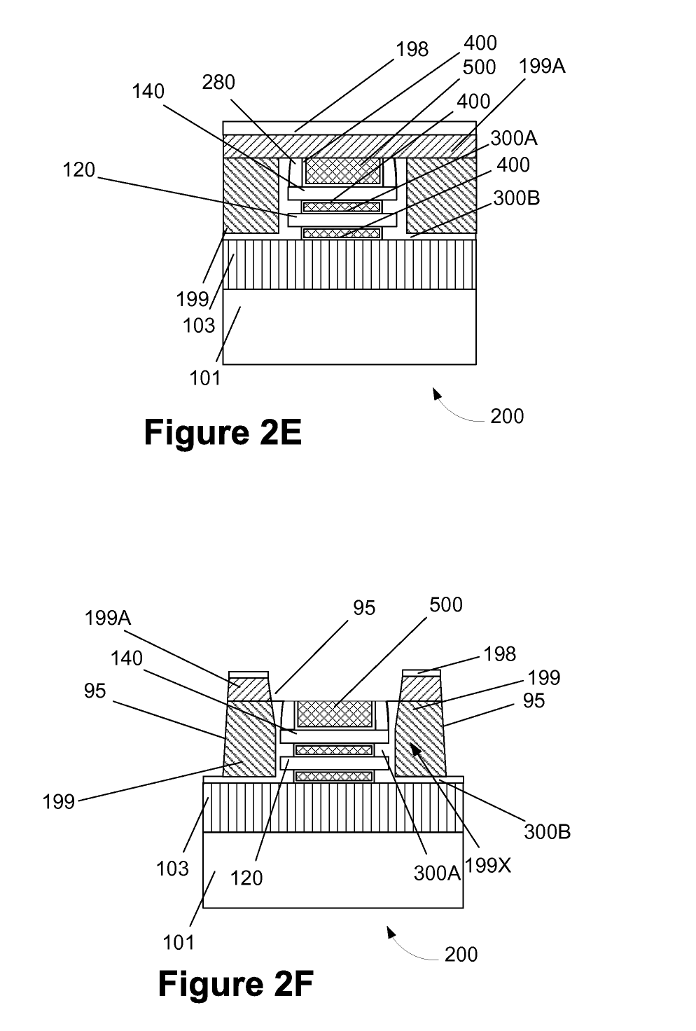

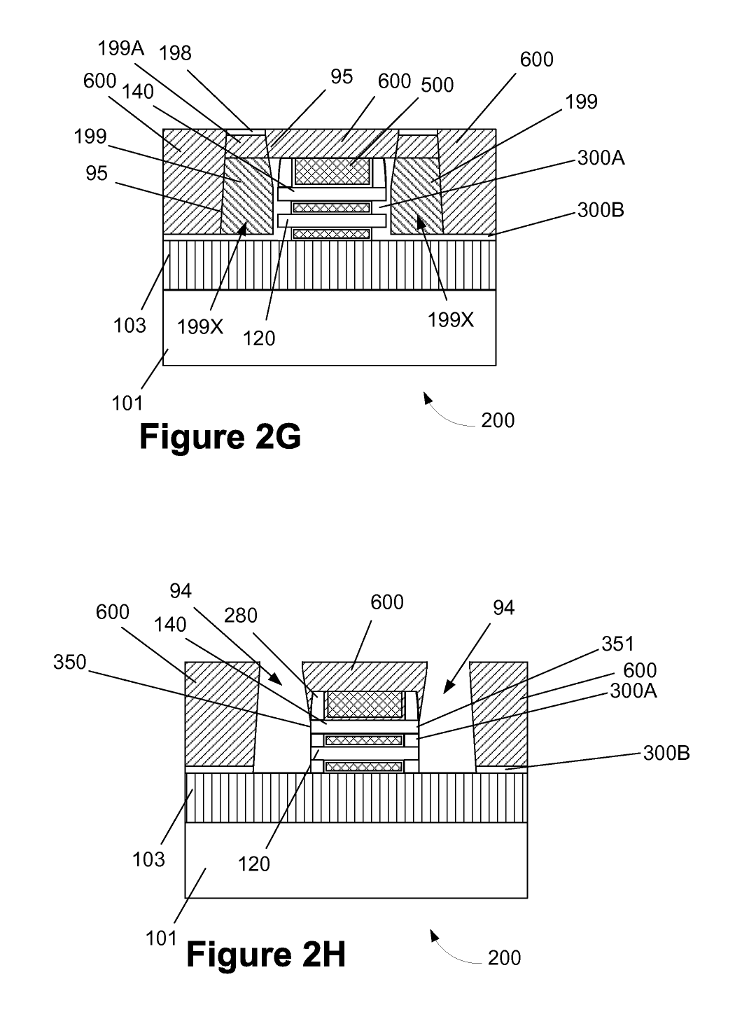

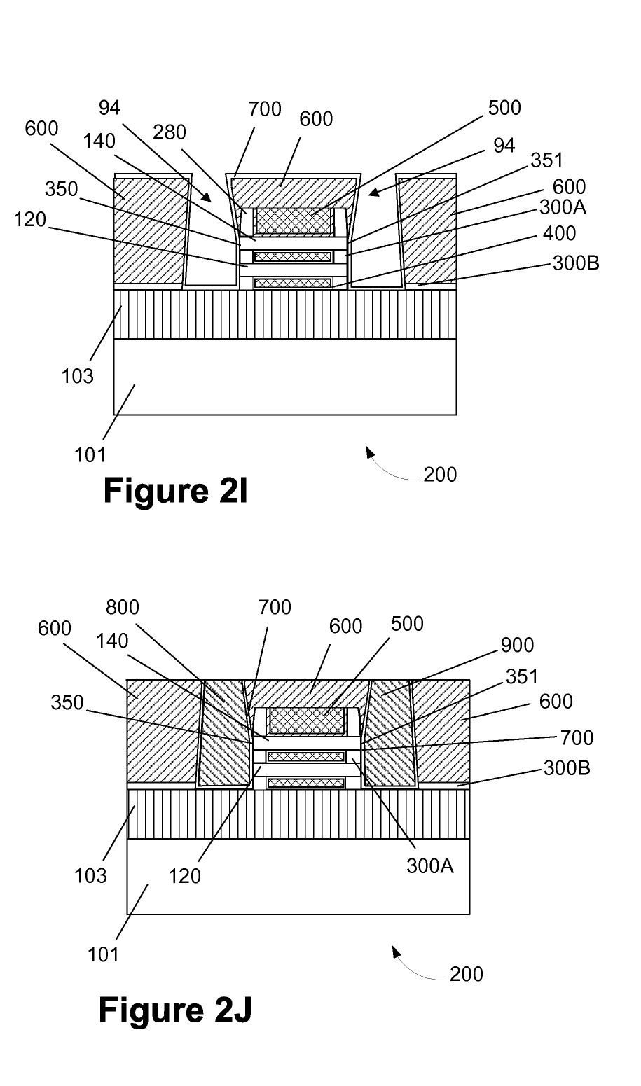

FIGS. 2A-2J depict various cross-sectional views of one illustrative embodiment of a nanowire device 200 that may be formed using the methods disclosed herein. In the illustrative example depicted herein, the device 200 will be depicted as including two illustrative nanowires. Of course, after a complete reading of the present application, those skilled in the art will appreciate that the methods disclosed herein may be employed to form a nanowire device with any desired number of nanowires, e.g., one or more nanowires. FIG. 2A illustrates an illustrative example wherein the nanowire device 200 is formed on an SiGeOI substrate. Specifically, the SiGeOI substrate includes a bulk silicon layer 101, a buried insulation layer 103, and a silicon germanium active layer 110. The buried insulation layer 103 includes silicon dioxide or sapphire in various embodiments.

FIG. 2A depicts the device 200 after several process operations were performed. First, various layers of semiconducting material 120, 130 and 140 were formed above the active layer 110. In general, in the depicted example, the layers 110 and 130 include a semiconductor material that may be selectively removed or etched relative to the materials used for the semiconducting material layers 120 and 140. As described more fully below, in the channel region of the device 200, portions of the semiconductor material layers 110 and 130 will be removed while the semiconducting material layers 120 and 140 are left in place as nanowires. Thus, the portions of the semiconducting material layers 110 and 130 within the channel region of the device 200 are sacrificial in nature. The semiconductor materials 120, 130 and 140 may include a variety of different materials such as, for example, silicon, a doped silicon, silicon/germanium, a III-V material, germanium, etc., and they may be formed to any desired thickness using any appropriate process, e.g., an epitaxial growth process, deposition plus ion implantation, etc. In one embodiment, the active layer 110 and the layer 130 are made of silicon/germanium, while the semiconducting material layers 120 and 140 are made of silicon. The thickness of the layers 110, 120, 130 and 140 may vary depending upon the application, and they may be formed to the same or different thicknesses.

Next, the illustrative gate structure 250 was formed above the layer 140. The illustrative gate structure 250 is intended to be representative in nature of any type of gate structure that may be formed on a nanowire device. In the depicted example, the gate structure 250 includes a gate insulation layer 250A, a gate electrode 250B and a gate cap layer 250C. A deposition process or thermal growth process may be performed to form the gate insulation layer 250A, which includes silicon dioxide in one embodiment. Thereafter, the material for the gate electrode 250B and the material for the gate cap layer 250C may be deposited above the device 200, and the layers may be patterned using known photolithographic and etching techniques. The gate electrode 250B may include a variety of, materials such as polysilicon or amorphous silicon. The gate cap layer 250C, the gate electrode 250B and the gate insulation layer 250A are sacrificial in nature as they will be removed at a later point during the formation of the device 200. Finally, the sidewall spacers 280 may be formed adjacent to the gate structure 250. The sidewall spacers 280 may be formed by depositing a layer of spacer material, such as silicon nitride, and thereafter performing an anisotropic etching process to define the spacers 280.

With continuing reference to FIG. 2A, one or more etching processes were performed to remove the exposed portions of the layers 110, 120, 130 and 140 using the gate structure 250 and the spacers 280 as an etch mask. The removal of the active layer 110 exposes the buried insulation layer 103 of the SiGeOI substrate 101. The patterning of the layers 120 and 140 results in those layers having exposed end surfaces 350, 351. As previously mentioned, for simplicity, the semiconductor materials depicted have a rectangular shape with sharp corners. However, if desired, the semiconductor materials may have a more rounded cylindrical configuration due to deposition and etch processes.

Next, the layers 110 and 130 were selectively recessed by performing one or more etching processes such that they have a shorter length (in the channel length (current transport) direction of the device 200), than do the layers 120 and 140. In at least one embodiment, the layers 110 and 130 are recessed enough such that the ends of the recessed materials 110 and 130 are approximately aligned with the interface between the sidewall spacers 280 and the gate electrode 250B as viewed in cross-section. Thereafter, a layer of insulating material 300 was conformably deposited over the gate structure 250, the spacers 280, and the now-exposed buried insulation layer 103. Deposition of the layer of material 300 overfilled the recesses defined by the recessed layers 110, 130. Portions 300A were created in the former recesses. Portions 300A are positioned adjacent to the ends of the recessed layers 110, 130 and between the ends of the layers 120, 140. The portion of layer 300 over the buried insulation layer 103 is referred to as 300B. The layer portions 300B may have a thickness of about 2-5 nm in one embodiment. In various embodiments, the layer of material 300 may be formed from any of a variety of different materials, e.g., a low-k material (k value less than about 3.3), a nitride, etc.

FIG. 2B depicts the device 200 after several process operations were performed. First, a layer of insulating material 199 was deposited on the device 200 and onto the layer portions 300B above the buried insulation layer 103. The layer or insulating material 199 may include an oxide material in at least one embodiment. A planarization process was performed on the layer of insulating material 199 that stopped on the gate cap layer 250C. Thereafter, one or more etching processes were performed to remove the gate cap layer 250C, the gate electrode 250B, and the gate insulation layer 250A. These etching processes resulted in the formation of a gate cavity 97 and exposes the layers 110, 120, 130 and 140 within the gate cavity 97 for further processing. With continuing reference to FIG. 2B, the layers 110 and 130 were removed via selective etching processes leaving the nanowires 120, 140 intact.

As shown in FIG. 2C, the next major process operation involves formation of a replacement gate structure in the gate cavity 97 and around the nanowires 120, 140. Accordingly, FIG. 2C depicts the device 200 after an illustrative gate insulation layer 400, e.g., a high-k material (k value greater than 10), was deposited on the device. Prior to the high-k deposition, a silicon thermal oxidation followed by a wet etch can be used to modify the silicon nanowire shape, e.g., to round the angles.

FIG. 2D depicts the device 200 after an illustrative replacement gate electrode 500 was formed in the gate cavity 97 and after a planarization process (CMP) was performed to remove excess materials positioned outside of the gate cavity 97 above the layer of insulating material 199. The replacement gate electrode 500 may also include a variety of conductive materials, such as polysilicon, as well as one or more metal layers that act as the gate electrode 500.

As shown in FIG. 2E, an additional insulation material layer 199A was formed above the layer of insulating material 199 and an etch-stop layer 198 was deposited onto the layer of insulating material 199A. The etch-stop layer 198 may be made of silicon nitride in at least one embodiment.

FIG. 2F depicts the device 200 after the layers 198, 199 and 199A were patterned by performing one or more etching processes through a patterned etch mask (not shown), such as a patterned layer of photoresist material. The etching processes resulted in the formation of openings 95 in the layers 198, 199A and 199 that will later be filled with an insulating material. Note that, during this etching process, the layer portions 300B protect the buried insulation layer 103 from removal when the portions of the layer 199 are removed. The remaining portions of the layers 198, 199A and 199 constitute a sacrificial or “dummy” MIS contact structure 199X for the device 200, as described more fully below. In at least one embodiment, prior to deposition of the layer 199A, the metal gate is recessed to form a cavity, a nitride film is deposited within the cavity, and the nitride is polished such that only a nitride cap remains over the metal gate. As such, the metal gate is enclosed by a nitride cap and a low-k side spacer material for protection during subsequent processing.

As shown in FIG. 2G, a layer of insulating material 600 was deposited so as to overfill the openings 95 in the layers 198, 199A and 199. Thereafter, a CMP process was performed using the etch-stop layer 198 as a polish-stop. In at least one embodiment, the layer of insulating material 600 may be made of a flowable silicon oxycarbide that is formed by performing a CVD process.

As shown in FIG. 2H, the remaining portions of the layer 198, 199A and 199, i.e., the sacrificial or “dummy” MIS contact structures 199X, were removed by performing one or more etching processes. These etching processes define MIS contact openings 94 in the layer of insulating material 600. In at least one embodiment shown in FIG. 2H, prior to MIS contact formation, the layer 300 is etched in the open cavity by means of a controlled isotropic etch. For example, the Frontier tool from Applied Materials may perform this etch. Consequently, the first and second ends 350, 351 of the layers 120, 140 are exposed. This etch, while removing portions 300B from over buried oxide 103, and 300 from over the sidewall, does not remove portions 300A and preserves the dielectric isolation in this area. In other embodiments (not depicted), the formation of the MIS contact openings 94 exposes the first and second ends 350, 351 of the layers 120, 140 except for the thin film 300 still present, i.e., the nanowire channel structure of the device 200. Note that, during this etching process, the layer portions 300B continue to protect the buried insulation layer 103 from removal when the portions of the layer 199 are removed.

As shown in FIG. 2I, an insulating liner layer 700 was conformably deposited into the MIS contact openings 94 and in contact with the first and second ends 350 and 351 of the nanowires 120, 140. The liner layer 700 may be made of a variety of different materials, such as a high-k material (material having a higher dielectric constant than about 10), titanium dioxide (TiO2), strontium titanate (SrTiO3), lanthanum oxide (La2O3), aluminum oxide (Al2O3), silicon dioxide (SiO2), silicon nitride (Si3N4), etc. The liner layer 700 may be formed to any desired thickness depending upon the particular application, e.g., between 5 angstroms and 10 nanometers thick.

As shown in FIG. 2J, a metal-containing source contact 800 and metal-containing drain contact 900 were formed on and in contact with the liner layer 700. Although not depicted, the contacts 800, 900 may also include one or more barrier layers (not shown) that are formed on the liner layer 700 prior to the bulk deposition of a conductive material, such as tungsten, that will overfill the remaining portions of the MIS contact openings 94. When present, such barrier layers should be considered to be part of the contact structures 800, 900. In various embodiments, the contacts 800, 900 comprise tungsten (W), titanium nitride (TiN), cobalt (Co), copper (Cu) and silver (Ag). After the MIS contact openings 94 are overfilled, a CMP process was performed to remove excess materials positioned above the layer of material 600 so as to arrive at the structure depicted in FIG. 2J.

In general, as will be appreciated by those skilled in the art after a complete reading of the present application, in the novel nanowire device 200 disclosed herein, a raised epi source drain region was not formed so as to establish contact to the nanowire structures 120, 140 as was done using prior art processing techniques. Rather, in the novel device disclosed herein, the first end surface 350 and the second end surface 351 of each of the nanowires 120, 140 is conductively coupled to their respective contact 800, 900 with only the liner layer 700 being positioned therebetween. The end of the nanowires 120 and 140 are vertically separated from each other by a low-k material 300A (a material having a dielectric constant less than about 3.3). The source/drain contacts 800, 900 are separated from the first and second end surfaces 350 and 351 of the nanowire channel structure by the liner layer 700 (one for each contact). As such, the device 200 allows the nanowires 120 and 140 to conduct substantially evenly when compared to each other, and each has a low and similar access resistance. Also, the anchoring of nanowires 120 and 140 within the device 200 introduces little to no defects. The creation of nanowires 120 and 140 with similar characteristics allows for improved performance, reliability and predictability.

The particular embodiments disclosed above are illustrative only, as the disclosure may be modified and practiced in different but equivalent manners apparent to those having the benefit of the teachings herein. Furthermore, no limitations are intended to the details of construction or design herein shown, other than as described in the claims below. It is therefore evident that the particular embodiments disclosed above may be altered or modified and all such variations are considered within the scope and spirit of the disclosure. Accordingly, the protection sought herein is as set forth in the claims below.

What is claimed:

1. A device, comprising:
a gate structure;
a nanowire channel structure positioned under said gate structure, said nanowire channel structure comprising first and second end surfaces;
a first insulating liner positioned on said first end surface;
a second insulating liner positioned on said second end surface;
a metal-containing source contact positioned on said first insulating liner; and
a metal-containing drain contact positioned on said second insulating liner.

2. The device of claim 1, wherein said first and second insulating liners comprise a material selected from the group consisting of a high-k material, titanium dioxide (TiO2), strontium titanate (SrTiO3), lanthanum oxide (La2O3), aluminum oxide (Al2O3), silicon dioxide (SiO2) and silicon nitride (Si3N4).

3. The device of claim 1, wherein said first and second insulating liners are each between 5 angstroms and 10 nanometers thick.

4. The device of claim 1, wherein said metal-containing source contact and said metal-containing drain contact comprise a material selected from the group consisting of tungsten (W), titanium nitride (TiN), cobalt (Co), copper (Cu) and silver (Ag).

5. The device of claim 1, wherein said nanowire channel structure comprises first and second nanowires and wherein said device further comprises a low-k material positioned adjacent said first and second end surfaces that vertically separates said first and second nanowires.

6. The device of claim 1, wherein said gate structure comprises a metal gate electrode.

7. The device of claim 1, wherein said nanowire channel structure comprises a plurality of nanowires.

8. A method, comprising:
forming a nanowire channel structure under a gate structure, said nanowire channel structure comprising first and second end surfaces;
depositing a first insulating liner on said first end surface;
depositing a second insulating liner on said second end surface;
forming a metal-containing source contact on said first insulating liner; and
forming a metal-containing drain contact on said second insulating liner.

9. The method of claim 8, wherein said first and second insulating liners comprise a material selected from the group consisting of a high-k material, titanium dioxide (TiO2), strontium titanate (SrTiO3), lanthanum oxide (La2O3), aluminum oxide (Al2O3), silicon dioxide (SiO2) and silicon nitride (Si3N4).

10. The method of claim 8, wherein said first and second insulating liners comprise titanium oxide.

11. The method of claim 8, wherein said first and second insulating liners are each between 5 angstroms and 10 nanometers thick.

12. The method of claim 8, further comprising forming a replacement gate structure.

13. The method of claim 8, wherein forming said nanowire channel structure comprises forming first and second nanowires and forming a low-k material, positioned adjacent to said first and second end surfaces, that vertically separates said first and second nanowires.

14. The method of claim 8, wherein said gate structure comprises a metal gate electrode.

15. The method of claim 8, wherein said first insulating liner is deposited concurrently with said second insulating liner.

16. The method of claim 8, wherein said metal-containing source contact is formed concurrently with the formation of said metal-containing drain contact.

17. A method, comprising:
forming a sacrificial contact structure comprising one or more layers of insulation material;
forming an insulating material around said sacrificial contact structure;
removing said sacrificial contact structure to form a contact opening within said insulating material so as to thereby expose an end surface of a nanowire channel structure;
depositing an insulating liner within said contact opening and on the exposed end surface of said nanowire channel structure; and
forming a metal-containing contact on said insulating liner within said contact opening.

18. The method of claim 17, wherein said insulating liner comprises a material selected from the group consisting of a high-k material, titanium dioxide (TiO2), strontium titanate (SrTiO3), lanthanum oxide (La2O3), aluminum oxide (Al2O3), silicon dioxide (SiO2) and silicon nitride (Si3N4).

19. The method of claim 17, wherein said insulating liner is between 5 angstroms and 10 nanometers thick.

20. The method of claim 17, wherein said metal-containing contact comprises a material selected from the group consisting of tungsten (W), titanium nitride (TiN), cobalt (Co), copper (Cu) and silver (Ag).
